(19) United States
(12) Patent Application Publication
(10) Pub. No.: US 2009/0104745 A1
(43) Pub. Date: Apr. 23, 2009

(54) INTEGRATION METHOD FOR DUAL DOPED POLYSILICON GATE PROFILE AND CD CONTROL

(76) Inventors: Hyesook Hong, Allen, TX (US); Luigi Colombo, Dallas, TX (US); Jinhan Choi, San Jose, CA (US)

Correspondence Address: TEXAS INSTRUMENTS INCORPORATED, P O BOX 655474, M/S 3999, DALLAS, TX, 75265, US

(21) Appl. No.: 11/877,124

(22) Filed: Oct. 23, 2007

(51) Int. Cl. H01L 21/336

(52) U.S. Cl. 438/283; 257/E21.421

(57) ABSTRACT

In accordance with the present teachings, methods of making dual doped polysilicon gates are provided. The method can include providing a semiconductor structure including a plurality of polysilicon gates having a first critical dimension disposed over a dielectric layer and planarizing the plurality of polysilicon gates with a spin-on material to form a plurality of planarized polysilicon gates. The method can further include doping an exposed first region with p-type dopants to form a plurality of p-doped planarized polysilicon gates and doping an exposed second region with n-type dopants to form a plurality of n-doped planarized polysilicon gates. The method can also include removing the spin-on material to form a plurality of p-doped polysilicon gates and a plurality of n-doped polysilicon gates, wherein critical dimension of each of the plurality of n-doped polysilicon gates and the plurality of p-doped polysilicon gates are substantially similar to the first critical dimension.

### DESCRIPTION OF THE INVENTION

1. Field of the Invention

The subject matter of this invention relates to methods of fabricating semiconductor devices. More particularly, the subject matter of this invention relates to the methods of fabricating dual doped polysilicon gates with controlled gate profile and critical dimension.

2. Background of the Invention

One of the problems faced by the semiconductor industry is gate profile and critical dimension (CD) control for nMOS and pMOS devices. This is especially true for the case where the polysilicon is doped differentially between nMOS and pMOS. In the case where an uncorrected reticle is used, an n-polysilicon to p-polysilicon CD difference of over 8 nm can be observed. Usually the problem is solved by adjusting the reticle CD to minimize gate CD differences between the n-polysilicon and the p-polysilicon devices. This method however requires a long process of reticle adjustment and limited selection for dopant. Furthermore, reticle adjustment can be costly, time consuming, and inflexible.

Thus, there is a need to overcome these and other problems of the prior art to provide methods of fabricating dual doped polysilicon gates with controlled gate profile and critical dimension.

### SUMMARY OF THE INVENTION

In accordance with the present teachings, there is a method of making a semiconductor device. The method can include providing a semiconductor structure including a plurality of polysilicon gates having a first critical dimension disposed over a dielectric layer and planarizing the plurality of polysilicon gates with a spin-on material to form a plurality of planarized polysilicon gates. The method can further include masking a first region of the plurality of planarized polysilicon gates and doping an exposed second region with n-type dopants to form a plurality of n-doped planarized polysilicon gates. The method can further include masking the second region including the plurality of n-doped planarized polysilicon gates and doping an exposed first region with p-type dopants to form a plurality of p-doped planarized polysilicon gates. The method can also include removing the spin-on material from the plurality of n-doped and the plurality of p-doped planarized polysilicon gates to form a plurality of p-doped polysilicon gates and a plurality of n-doped polysilicon gates, wherein critical dimension of each of the plurality of n-doped polysilicon gates and the plurality of p-doped polysilicon gates are substantially similar to the first critical dimension.

According to another embodiment of the present teachings, there is a method of making dual doped polysilicon gates. The method can include providing a semiconductor structure including a plurality of polysilicon gates having a first critical dimension disposed over a dielectric layer, forming an offset spacer surrounding each of the plurality of polysilicon gates, and planarizing the plurality of polysilicon gates with a spin-on material to form a plurality of planarized polysilicon gates. The method can also include masking a first region of the plurality of planarized polysilicon gates and doping an exposed second region with n-type dopants to form a plurality of n-doped planarized polysilicon gates. The method can further include masking the second region including the plurality of n-doped planarized polysilicon gates and doping the exposed first region with p-type dopants to form a plurality of p-doped planarized polysilicon gates. The method can also include removing the spin-on material from the plurality of n-doped and the p-doped planarized polysilicon gates to form a plurality of n-doped polysilicon gates and a plurality of p-doped polysilicon gates, wherein critical dimension of each of the plurality of n-doped polysilicon gates and the plurality of p-doped polysilicon gates are substantially similar to the first critical dimension.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1A-1H illustrate an exemplary method of making dual doped polysilicon gates, according to various embodiment of the present teachings.

FIGS. 2A-2I illustrate an exemplary method of making a semiconductor device, in accordance with various embodiments of the present teachings.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

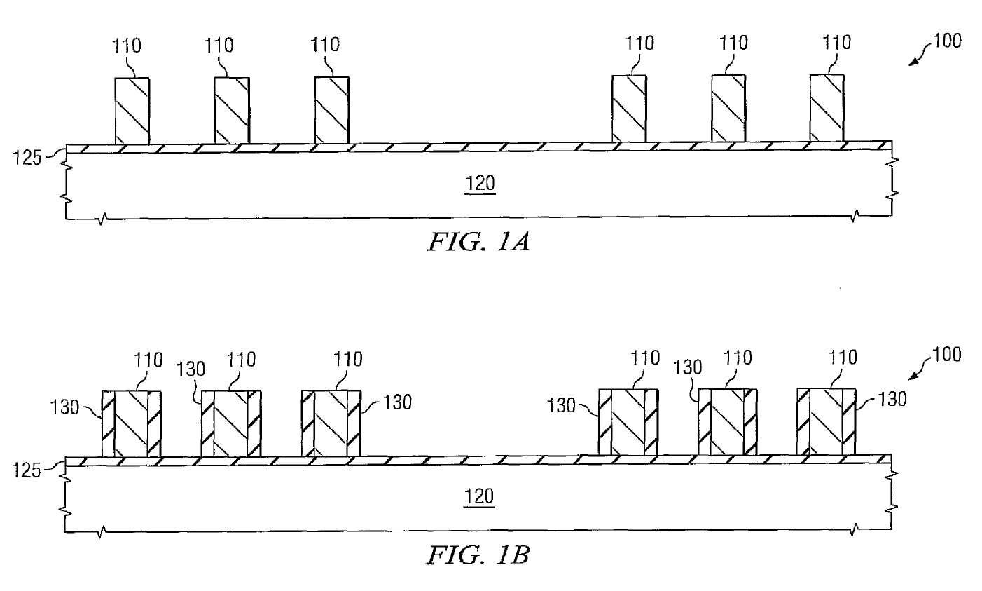

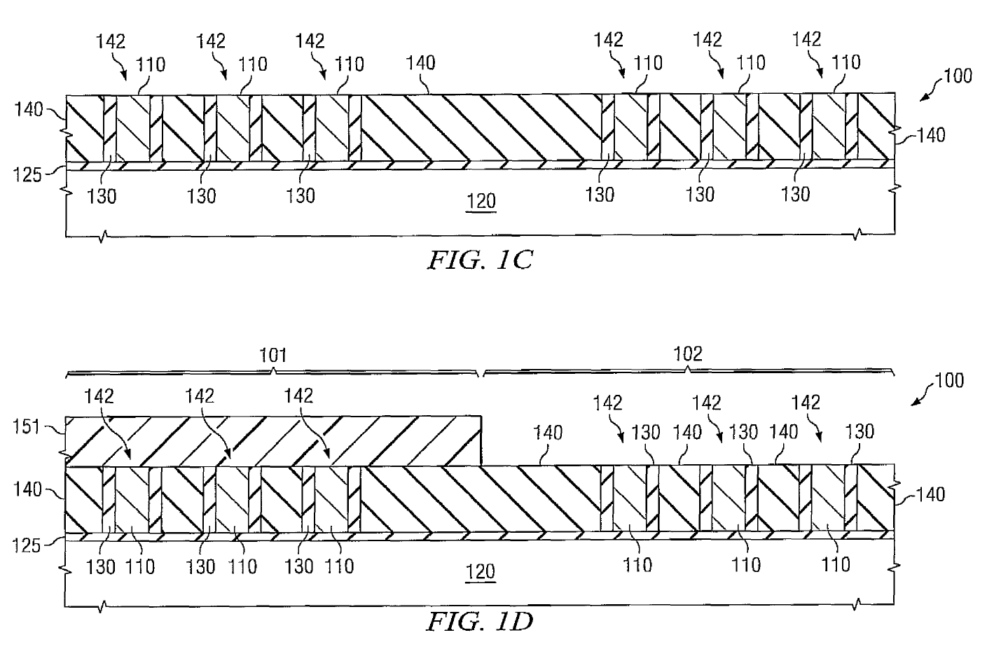

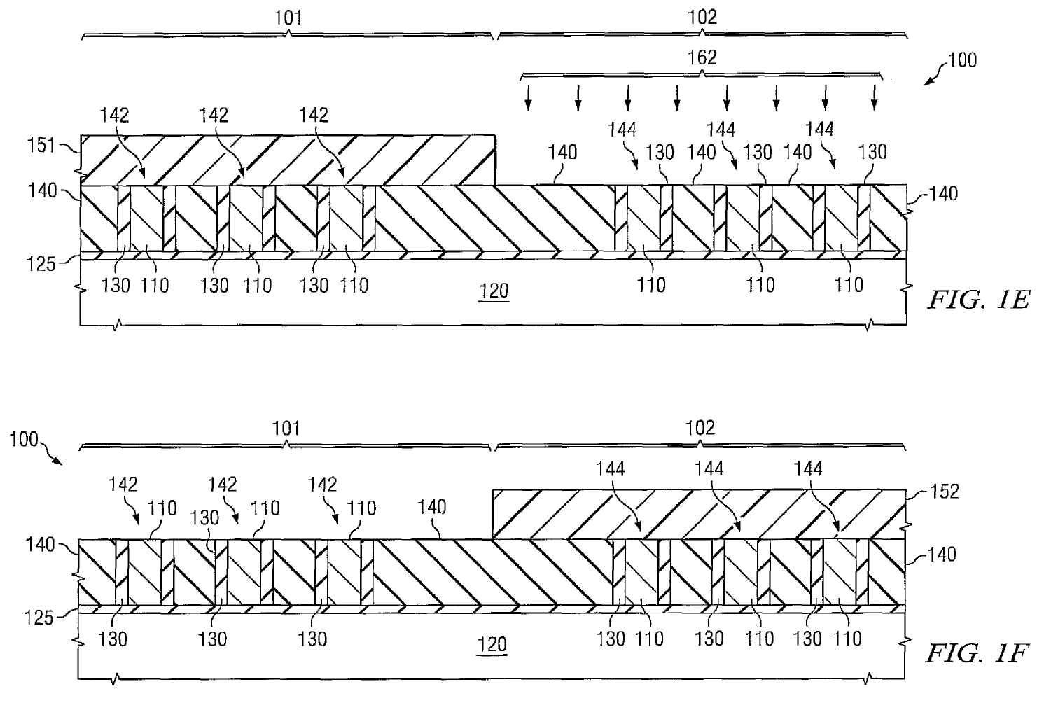

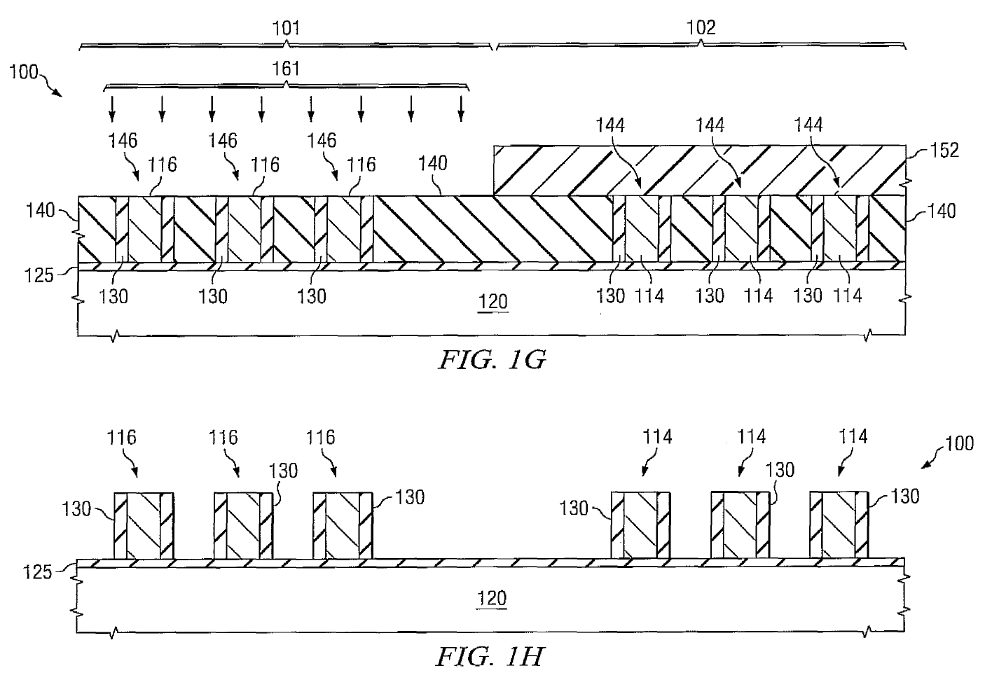

FIGS. 1A-1H illustrate an exemplary method of making dual doped polysilicon gates 114, 116. The method can include providing a semiconductor structure 100 including a plurality of polysilicon gates 110 having a first critical dimension disposed over a dielectric layer 125, as shown in FIG. 1A. In various embodiments, the dielectric layer 125 can include one or more of an oxide layer and a nitrided oxide layer. In some embodiments, the dielectric layer 125 can be disposed over a substrate 120. Any suitable substrate 120 can be used, such as, for example, silicon. In other embodiments, the substrate 120 can include a well region (not shown), which can be, for example, an n-well or a p-well, as is well known in the art. In some embodiments, the substrate 120 can also include source and drain regions and source and drain extensions in the well region. In certain embodiments, the substrate 120 can also include any suitable isolation structures (not shown), such as, for example, a shallow trench isolation structure (STI), LOCOS structure.

The method of making dual doped polysilicon gates 114, 116 can also include forming an offset spacer 130 surrounding each of the plurality of polysilicon gates 110, as shown in FIG. 1B. In various embodiments, the step of forming an offset spacer 130 surrounding each of the plurality of polysilicon gates 110 can include depositing one or more layers of an oxide, a nitride, and an oxynitride. Any suitable method can be used for the deposition of the one or more layers of an oxide, a nitride, and an oxynitride, such as, for example, thermal deposition, chemical vapor deposition, or combination of two. In various embodiments, the offset spacer 130 can have a thickness from about 10 Å to about 150 Å. In various embodiments, the step of forming an offset spacer 130 surrounding each of the plurality of polysilicon gates 110 can include depositing one or more layers of an oxide, a nitride, and an oxynitride over each of the plurality of polysilicon gates 110 and removing the one or more layers of an oxide; a nitride, and an oxynitride from the top surface of each of the plurality of polysilicon gates 110, thereby exposing the top surface of each of the plurality of polysilicon gates 110. The method of making dual doped polysilicon gates 114, 116 can further include planarizing the plurality of polysilicon gates 110 with a spin-on material 140 to form a plurality of planarized polysilicon gates 142, as shown in FIG. 1C. In some embodiments, the spin-on material 140 can include one or more of an organic material, an inorganic material, and a hybrid organic-inorganic material, such as, for example silicon-on glass (SOG) and bottom anti-reflective coating (BARC). In various embodiments, the step of planarizing the plurality of polysilicon gates 110 with a spin-on material 140 can include depositing a layer of spin-on material 140 over the dielectric layer 125 and the polysilicon gates 110 and removing a substantial amount of spin-on material 140 from the top of the plurality of polysilicon gates 110 to form the plurality of planarized polysilicon gates 142. In some embodiments, a substantial amount of spin-on material 140 from the top of the plurality of polysilicon gates 110 can be removed by any suitable method, such as, for example, chemical and/or physical etching and chemical mechanical polishing. In various embodiments, the spin-on material 140 can be removed from the top of the plurality of polysilicon gates 110 such that the top surface of each of the plurality of polysilicon gates 110 can be exposed.

The method of making dual doped polysilicon gates 114, 116 can further include masking a first region 101 of the plurality of planarized polysilicon gates 142, as shown in FIG. 1D. In various embodiments, the step of masking the first region 101 can include forming a resist layer over the plurality of planarized polysilicon gates 142, patterning, and developing the resist layer to form a mask 151 over the first region 101 and an exposed second region 102. One of ordinary skill in the art would know that other conventional techniques can be used for patterning and developing the resist. The method of making dual doped polysilicon gates 114, 116 can also include doping 162 an exposed second region 102 with n-type dopants to form a plurality of n-doped planarized polysilicon gates 144, as shown in FIG. 1E. The mask 151 protects the plurality of planarized polysilicon gates 142 in the first region 101 from doping 162. In various embodiments, n-type dopants, such as, for example, phosphorus, arsenic, or antimony can be implanted in the planarized polysilicon gates 142 in any desired dopant concentration. Suitable energy and dose for the implantation of the n-type dopant can be determined by one of ordinary skill in the art, as the energy and dose are dependent upon the thickness of the polysilicon gates 110 and chemical/physical properties of the implant species in the polysilicon gates 110. After the doping, the mask 151 can be removed. The method can further include masking the second region 102 including the plurality of n-doped planarized polysilicon gates 144, as shown in FIG. 1F. In various embodiments, the step of masking the second region 102 can include forming a resist layer over the plurality of planarized polysilicon gates 142 and the plurality of n-doped planarized polysilicon gates 144, patterning, and developing the resist layer to form a mask 152 over the second region 102 including the plurality of n-doped planarized polysilicon gates 144 and an exposed first region 101. The method can further include doping 161 the exposed first region 101 with p-type dopants to form a plurality of p-doped planarized polysilicon gates 146, as shown in FIG. 1G. Any suitable p-type dopant can be used, such as, for example, boron. Suitable energy and dose for the implantation of the p-type dopant can be determined by one of ordinary skill in the art, as the energy and dose are dependent upon the thickness of the polysilicon gates 110 and chemical/physical properties of implant species in the polysilicon gates 110. The mask 152 protects the plurality of n-doped planarized polysilicon gates 144 in the second region 102 from doping 161. The mask 152 over the second region 102 including the plurality of n-doped planarized polysilicon gates 144 can be removed after the implantation of p-type dopants in the first region 101 is completed. The method can further include removing the spin-on material 140 from the plurality of n-doped planarized polysilicon gates 144 and the plurality of p-doped planarized polysilicon gates 146 to form a plurality of n-doped polysilicon gates 114 and a plurality of p-doped polysilicon gates 116, as shown in FIG. 1H. The spin-on-material 140 can be removed by any suitable method such as, for example, ashing, chemical and/or physical etching. In various embodiments, critical dimension of each of the plurality of n-doped polysilicon gates 114 and the plurality of p-doped polysilicon gates 116 can be substantially similar to the first critical dimension. The method of making dual doped polysilicon gates 114, 116 can further include annealing the plurality of n-doped polysilicon gates and the plurality of p-doped polysilicon gates at any suitable temperature. Examples of suitable temperature can range from about 500° C. to about 1000° C. In an exemplary embodiment, the plurality of n-doped polysilicon gates and the plurality of p-doped polysilicon gates can be annealed at a temperature from about 650° C. to about 950° C. for a period of time ranging from about 1 millisecond to about 30 minutes. Any suitable annealing method can be used, including, but not limited to, conventional rapid thermal annealing (RTA) and laser annealing.

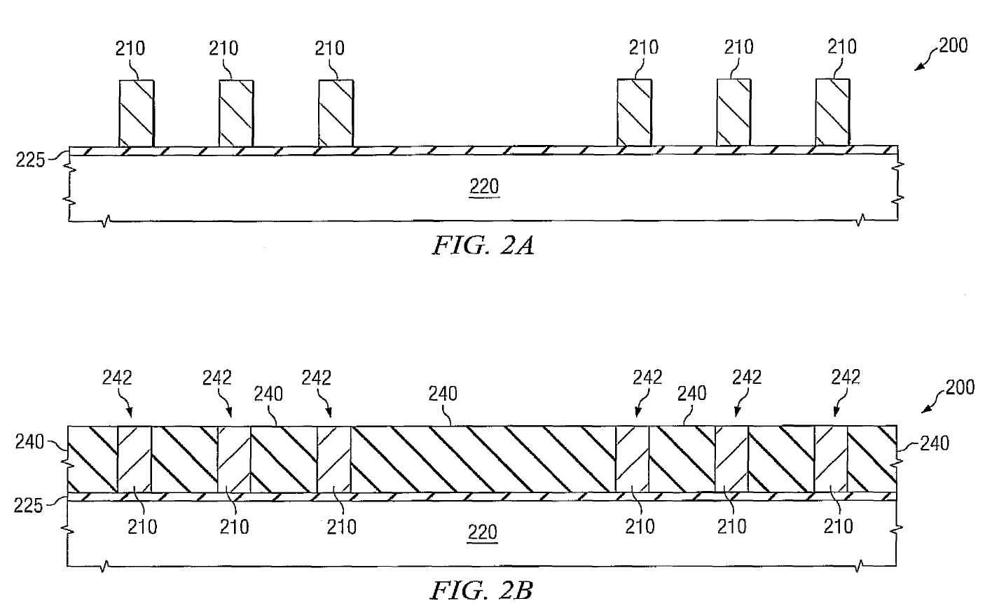

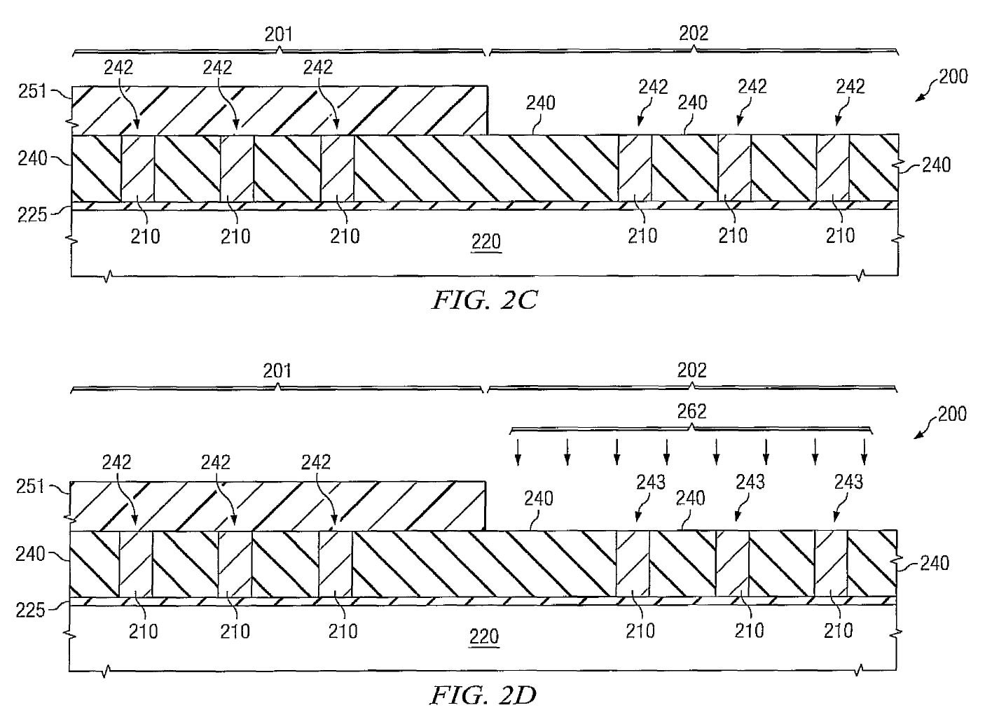

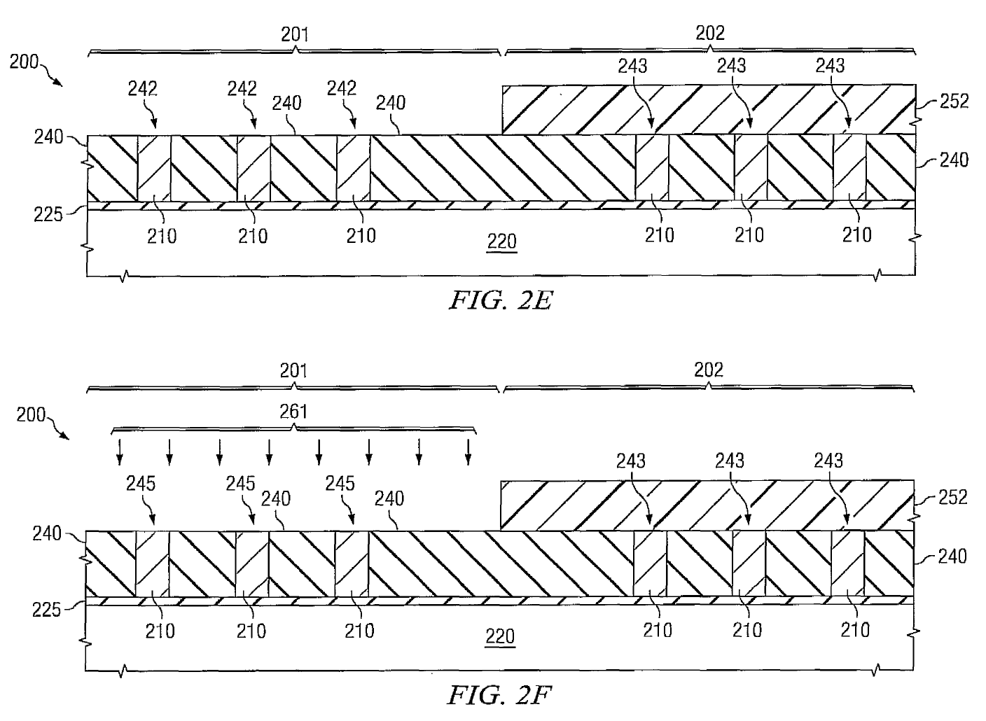

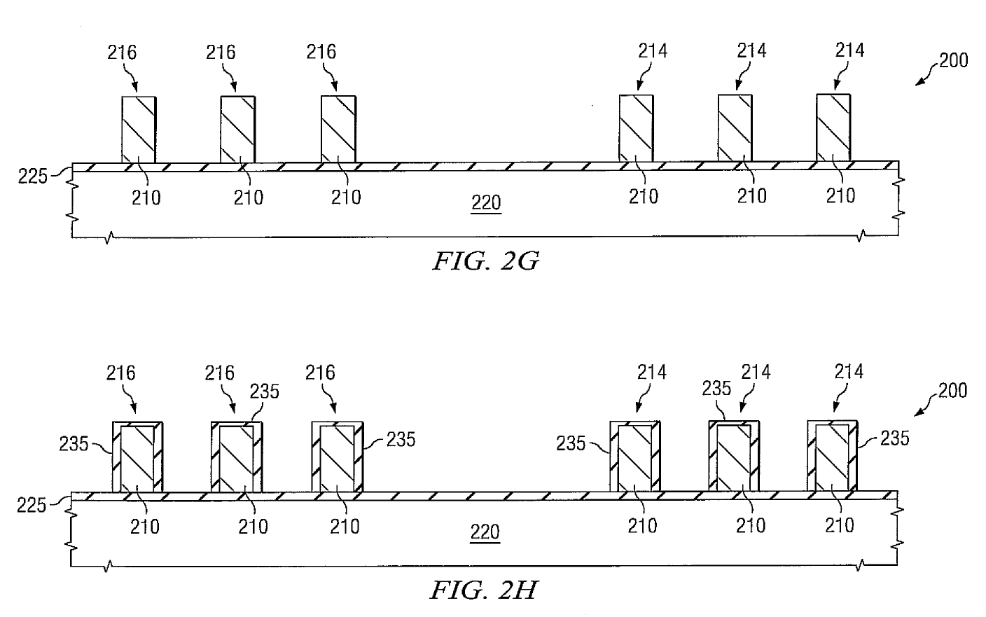

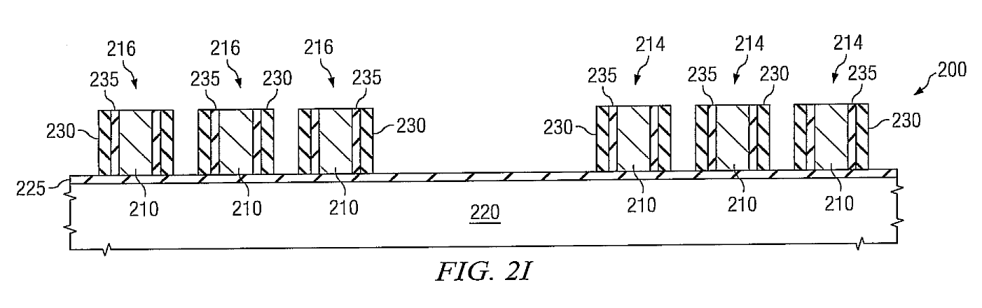

FIGS. 2A-2F illustrate an exemplary method of making a semiconductor device 200 according to various embodiments of the present teachings. The method can include providing a semiconductor structure including a plurality of polysilicon gates 210 having a first critical dimension disposed over a dielectric layer 225, as shown in FIG. 2A and planarizing the plurality of polysilicon gates 210 with a spin-on material 240 to form a plurality of planarized polysilicon gates 242, as shown in FIG. 2B. In some embodiments, the spin-on material 240 can include one or more of an organic material, an inorganic material, and a hybrid organic-inorganic material, such as, for example, silicon on glass (SOG) and bottom anti-reflective coating (BARC). The method can also include masking a first region 201 of the plurality of planarized polysilicon gates 242, as shown in FIG. 2C by first forming a resist layer over the plurality of planarized polysilicon gates 242, then patterning, and finally developing the resist layer to form a mask 251 over the first region 201. The method can further include doping an exposed second region 202 with n-type dopants to form a plurality of n-doped planarized polysilicon gates 243, as shown in FIG. 2D. Any suitable n-type dopant can be used, such as, for example, phosphorus, arsenic, and antimony. The method of making a semiconductor device 200 can further include removing the mask 251, masking the second region 202 with a mask 252, and doping an exposed first region 201 with p-type dopants to form a plurality of p-doped planarized polysilicon gates 245, as shown in FIGS. 2E and 2F. Any suitable p-type dopant can be used, such as, for example, boron. Suitable energy and dose for the implantation of the n-type dopants and the p-type dopants can be determined by one of ordinary skill in the art, as the energy and dose are dependent upon the thickness of the polysilicon gates 210 and chemical/physical properties of the implant species in the polysilicon gates 110. The method of making a semiconductor device 200 can further include removing the mask 252 and removing the spin-on material 240 from the plurality of n-doped planarized polysilicon gates 243 and the plurality of p-doped planarized polysilicon gates 245 to form a plurality of n-doped polysilicon gates 214 and a plurality of p-doped polysilicon gates 216, as shown in FIG. 2G. In various embodiments, critical dimension of each of the n-doped polysilicon gates 214 and the p-doped polysilicon gates 216 can be substantially similar to the first critical dimension. In various embodiments, the spin-on material 240 can be removed from the plurality of n-doped planarized polysilicon gates 243 and the plurality of p-doped planarized polysilicon gates 245 using one or more of ashing, chemical, and/or physical etching. In some embodiments, the method can also include forming a thin layer of oxide 235 over the plurality of n-doped polysilicon gates 214 and the plurality of p-doped polysilicon gates 216, as shown in FIG. 2H and annealing the plurality of n-doped polysilicon gates 214 and the plurality of p-doped polysilicon gates 216 at a temperature from about 650° C. to about 950° C. for a period of time ranging from about 1 second to about 10 minutes. Any suitable annealing method can be used, including, but not limited to, conventional rapid thermal annealing (RTA) and laser annealing. In some embodiments, the method can also include forming an offset spacer 230 surrounding the thin layer of oxide 235, as shown in FIG. 2I. In various embodiments, the step of forming an offset spacer 230 can include forming one or more layers of an oxide, a nitride, and an oxynitride. Any suitable method can be used for the deposition of the thin oxide layer 235 and the offset spacer 230, such as, for example, thermal deposition, chemical vapor deposition or combination of two. In some embodiments, the thin layer of oxide 235 can have a thickness from about 10 Å to about 50 Å. In other embodiments, the offset spacer 230 can have a thickness from about 10 Å to about 150 Å.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “X comprises one or more of A, B, and C” means that X can include any of the following: either A, B, or C alone; or combinations of two, such as A and B, B and C, and A and C; or combinations of three A, B and C.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of making a semiconductor device, the method comprising:
providing a semiconductor structure comprising a plurality of polysilicon gates having a first critical dimension disposed over a dielectric layer;
planarizing the plurality of polysilicon gates with a spin-on material to form a plurality of planarized polysilicon gates;
masking a first region of the plurality of planarized polysilicon gates;
doping an exposed second region with n-type dopants to form a plurality of n-doped planarized polysilicon gates;
masking the second region comprising the plurality of n-doped planarized polysilicon gates;
doping an exposed first region with p-type dopants to form a plurality of p-doped planarized polysilicon gates; and
removing the spin-on material from the plurality of n-doped and the plurality of p-doped planarized polysilicon gates to form a plurality of p-doped polysilicon gates and a plurality of n-doped polysilicon gates, wherein critical dimension of each of the plurality of n-doped polysilicon gates and the plurality of p-doped polysilicon gates are substantially similar to the first critical dimension.

2. The method of claim 1, wherein the step of planarizing the plurality of polysilicon gates with a spin-on material to form the plurality of planarized polysilicon gates comprises:
depositing a layer of spin-on-material over the dielectric layer and the plurality of polysilicon gates; and
removing a substantial amount of spin-on-material from the top of the plurality of polysilicon gates.

3. The method of claim 2, wherein the step of removing a substantial amount of spin-on-material comprises one or more of etching back spin-on-material and chemical mechanical polishing spin-on-material.

4. The method of claim 1, wherein the step of planarizing the plurality of polysilicon gates with a spin-on material comprises depositing one or more of an organic material, an inorganic material, and a hybrid organic-inorganic material.

5. The method of claim 1, wherein the step of masking a first region of the plurality of planarized polysilicon gates comprises:
forming a resist layer over the plurality of planarized polysilicon gates;
patterning the resist layer; and
developing the resist layer to form a masked first region and an exposed second region.

6. The method of claim 1, wherein the step of masking the second region comprising the plurality of n-doped planarized polysilicon gates comprises:
forming a resist layer over the plurality of planarized polysilicon gates comprising the n-doped planarized polysilicon gates;
patterning the resist layer; and
developing the resist layer to form a masked second region comprising the plurality of n-doped planarized polysilicon gates and an exposed first region.

7. The method of claim 1, wherein the step of removing the spin-on material from the plurality of n-doped and the plurality of p-doped planarized polysilicon gates comprises using one or more of ashing, chemical etching, and physical etching.

8. The method of claim 1 further comprising annealing the plurality of n-doped polysilicon gates and the plurality of p-doped polysilicon gates at a temperature from about 650° C. to about 950° C. for a period of time ranging from about 1 millisecond to about 30 minutes.

9. The method of claim 1 further comprising:
forming a thin layer of oxide over the plurality of n-doped polysilicon gates and the plurality of p-doped polysilicon gates; and
annealing the plurality of n-doped polysilicon gates and the plurality of p-doped polysilicon gates at a temperature from about 650° C. to about 950° C. for a period of time ranging from about 1 second to about 10 minutes.

10. The method of claim 9 further comprising forming an offset spacer surrounding the thin layer of oxide.

11. The method of claim 10, wherein the step of forming an offset spacer comprises depositing one or more layers of an oxide, a nitride, and an oxynitride.

12. A method of making dual doped polysilicon gates, the method comprising:
providing a semiconductor structure comprising a plurality of polysilicon gates having a first critical dimension disposed over a dielectric layer;
forming an offset spacer surrounding each of the plurality of polysilicon gates;
planarizing the plurality of polysilicon gates with a spin-on material to form a plurality of planarized polysilicon gates;
masking a first region of the plurality of planarized polysilicon gates;
doping an exposed second region with n-type dopants to form a plurality of n-doped planarized polysilicon gates;
masking the second region comprising the plurality of n-doped planarized polysilicon gates;
doping the exposed first region with p-type dopants to form a plurality of p-doped planarized polysilicon gates; and
removing the spin-on material from the plurality of n-doped and the p-doped planarized polysilicon gates to form a plurality of n-doped polysilicon gates and a plurality of p-doped polysilicon gates, wherein critical dimension of each of the plurality of n-doped polysilicon gates and the plurality of p-doped polysilicon gates are substantially similar to the first critical dimension.

13. The method of claim 12, wherein the step of forming an offset spacer surrounding each of the plurality of polysilicon gates comprises depositing one or more layers of an oxide, a nitride, and an oxynitride.

14. The method of claim 12 further comprising forming a thin layer of silicon oxide over each of the plurality of polysilicon gates before the step of forming an offset spacer.

15. The method of claim 12, wherein the step of planarizing the plurality of polysilicon gates with a spin-on material to form a plurality of planarized polysilicon gates comprises:
depositing a layer of spin-on material over the dielectric layer and the plurality of polysilicon gates; and
removing a substantial amount of spin-on material from the top of the plurality of the polysilicon gates.

16. The method of claim 14, wherein the step of removing a substantial amount of spin-on material comprises one or more of etching back spin-on-material and chemical mechanical polishing spin-on-material.

17. The method of claim 12, wherein the step of planarizing the plurality of polysilicon gates with a spin-on material comprises depositing one or more of an organic material, an inorganic material, and a hybrid organic-inorganic material.

18. The method of claim 12 further comprising annealing the plurality of p-doped polysilicon gates and the plurality of n-doped polysilicon gates at a temperature from about 650° C. to about 950° C. for a period of time ranging from about 1 millisecond to about 30 minutes.
